(19) United States
(12) Patent Application Publication
(10) Pub. No.: US 2020/0373824 A1
(43) Pub. Date: Nov. 26, 2020

(54) SYSTEMS AND APPARATUSES FOR ENERGY HARVESTING

(71) Applicant: Daniel APO, Pflugerville, TX (US)

(72) Inventor: Daniel APO, Pflugerville, TX (US)

(21) Appl. No.: 16/635,292

(22) PCT Filed: Jul. 31, 2017
(86) PCT No.: PCT/US2017/044628

§ 371 Date: Jan. 30, 2020

(51) Int. Cl. H02K 35/02; F03G 7/08; H01L 41/113; H02N 1/08; H02N 2/18

(52) U.S. Cl. CPC H02K 35/02; F03G 7/08; H02N 2/186; H02N 1/08; H01L 41/1138

(57) ABSTRACT

Various embodiments described herein provide for energy harvesting using one or more of electromagnetic, piezoelectric, and electrostatic transduction mechanisms to convert movement or vibration into electric energy. Some embodiments may comprise an energy harvesting component, or a system of energy harvesting components, that converts kinetic energy from movement or vibration into electric energy. Additionally, some embodiments may be adapted or configured for use within a mobile device (e.g., a mobile phone or a smartphone) or a wearable device (e.g., a smartwatch) such that motion or vibration felt within the mobile/wearable device can be converted by those embodiments into electric energy, which can assist in recharging the mobile/wearable device's battery.

### TECHNICAL FIELD

The present disclosure relates generally to energy harvesting, and more particularly, various embodiments described herein provide systems and apparatuses for harvesting energy utilizing mechanical, magnetic or fluidic motion.

### BACKGROUND

Today, basic usage of smartphones (e.g., phone calls, texting, and data applications) and wearable devices (e.g., smartwatch, fitness monitoring device, and medical monitoring device) can lead to a need for recharging the smartphone multiple times a day. Unfortunately, advancements in battery technologies are not keeping up with advancements in smartphones, wearable devices, and other mobile devices and, as a result, newer wearable and mobile devices are usually equipped with large batteries just to keep up with basic power needs. As solutions for extending battery life, manufacturers have introduced various accessories, such as external harvesters, power banks, power cases, and power mats. While some of these solutions have been shown to help extend the battery life of wearable devices and mobile devices, they can often be burdensome or require energy sources that are not always available (e.g., thermal and solar). As such, existing solutions for extending battery life of wearable devices and mobile devices can be less than desirable or insufficient, especially with respect to smartphones.

### BRIEF DESCRIPTION OF THE DRAWINGS

In the drawings, which are not necessarily drawn to scale, like numerals may describe similar components in different views. To easily identify the discussion of any particular element or act, the most significant digit or digits in a reference number refer to the figure number in which the corresponding element is first introduced. Some embodiments are illustrated by way of example, and not limitation, in the figures of the accompanying drawings.

FIG. 1 is a diagram illustrating an example energy harvesting connector, according to some embodiments.

FIG. 2 is a diagram illustrating an example energy harvesting component, according to some embodiments.

FIG. 3 is a heat map illustrating an example average magnetic flux density from a magnetic ring of an energy harvesting component, according to some embodiments.

FIGS. 4A-4B are diagrams illustrating an example energy harvesting component, according to some embodiments.

FIG. 5 is a diagram illustrating an example energy harvesting component, according to some embodiments.

FIG. 6 is a diagram illustrating an example energy harvesting connector, according to some embodiments.

FIGS. 7-9 are diagrams illustrating example energy harvesting systems, according to some embodiments.

FIG. 10 is a chart illustrating an example velocity versus frequency of a magnetic ring of a straight energy harvesting component in an energy harvesting system, according to some embodiments.

FIG. 11 is a chart illustrating an example voltage output of an energy harvesting system during operation, according to some embodiments.

FIG. 12 is a chart illustrating an example average magnetic flux density intersecting an inner coil and an outer coil of a straight energy harvesting component, according to some embodiments.

FIG. 13 is a diagram illustrating an example energy harvesting system, according to some embodiments.

FIGS. 14A-14B provide multiple diagrams illustrating example configurations of energy harvesting systems, according to some embodiments.

### DETAILED DESCRIPTION

Various embodiments described herein provide for energy harvesting using one or more of electromagnetic, piezoelectric, and electrostatic transduction mechanisms to convert movement or vibration into electric energy. Some embodiments may comprise an energy harvesting component, or a system of energy harvesting components, that converts kinetic energy from movement or vibration into electric energy. Additionally, some embodiments may be adapted or configured for use within a mobile device (e.g., a mobile phone or a smartphone) or a wearable device such that motion or vibration felt within the mobile device/wearable device can be converted by those embodiments into electric energy, which can assist in recharging the mobile device/wearable device's battery. Such embodiments can enable implementation of a movement-powered smartphone that is powered internally by an energy harvesting component or a system of energy harvesting components. Depending on the embodiment, the motion or vibration received (e.g., felt) by various embodiments may be the result of usage of the mobile device or the wearable device. With respect to mobile devices, this can include the mobile device's user making a phone call, using an application on the mobile device, or moving the mobile device from one location to another (e.g., carrying it in the user's pocket). With respect to wearable devices, this can include carrying the wearable device while walking or while engaged in physical fitness. In this way, various embodiments can extend a battery life a mobile device or a wearable device by movement of the mobile/wearable device and can do so seamlessly without need of an external power source, such as an alternating current (AC) recharger, a universal serial bus (USB) port, or an external battery extender coupled to the mobile/wearable device.

According to some embodiments, an energy harvesting system is provided that comprises at least one energy harvesting component described herein coupled to at least one energy harvesting connector described herein. For a given energy harvesting system, two energy harvesting components may be coupled together by way of an energy harvesting connector. In this way, a plurality of energy harvesting components can be chained together by using energy harvesting connectors between energy harvesting components. An energy harvesting system described herein may provide an energy harvesting by combining electromagnetic transduction with magneto-fluidic control. In particular, the system may use the principle of motion or vibrational energy harvesting to receive low-frequency motion or vibration (e.g., via an energy harvesting component described herein) and convert the received motion or vibration into electric energy. By way of example, the low frequency may comprise a range from 0.5 Hz to 100 Hz. Example activities that may cause low-frequency motion or vibration can include, without limitation, walking (1 Hz), jogging (2 Hz), and riding in a car (3-8 Hz). Additionally, the system may receive motion or vibration in one dimension (e.g., X), two dimensions (e.g., X and Y axes) or three dimensions (e.g., X, Y, and Z axes), and convert the received motion or vibration into electric energy.

For instance, an energy harvesting system of an embodiment may comprise at least one of several variations, each of which receives vibration and converts the vibration to electric energy. The following embodiments of energy harvesting components are merely described for illustrative purposes and in no way limit the possibility of other embodiments. One embodiment of an energy harvesting system may comprise a straight energy harvesting component to receive vibration in one dimension (e.g., X dimension) and convert the received vibration to electric energy in that one dimension.

In another embodiment, an energy harvesting system may comprise a plurality of straight energy harvesting components and a plurality of energy harvesting connectors coupled to the straight energy harvesting components, such that the straight energy harvesting components and the energy harvesting connectors are arranged to form a cube. Such an embodiment may receive vibration in three dimensions (e.g., X, Y, and Z dimensions) and convert the received vibration to electric energy in the three dimensions. Additionally, such an embodiment may be suitable for powering a bulky electric device or an electric device with similar length, breadth, or thickness to that of the energy harvesting system.

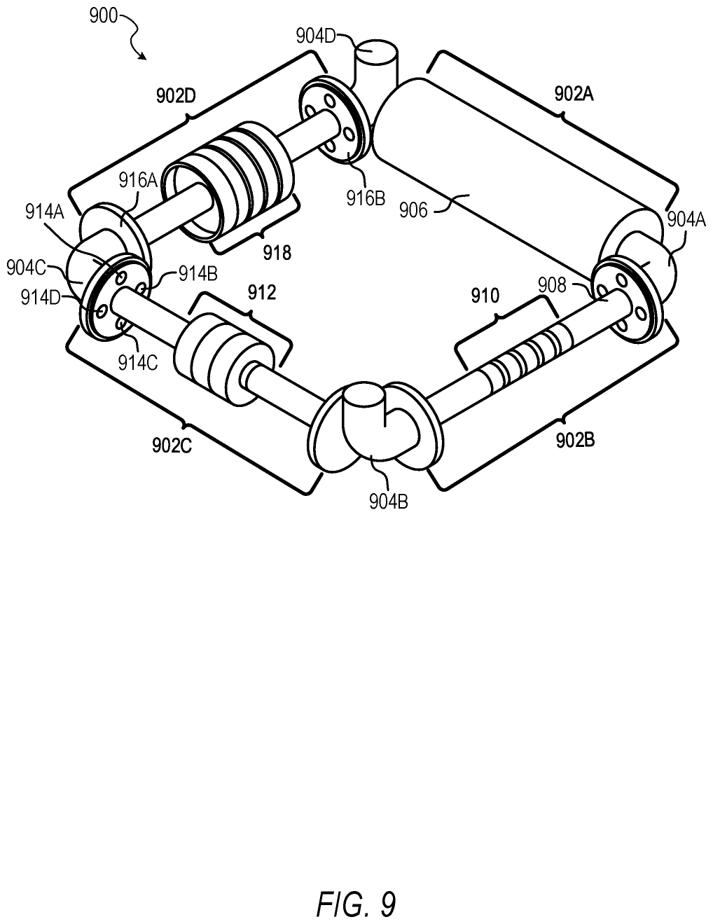

In yet another embodiment, an energy harvesting system may comprise a plurality of straight energy harvesting components and a plurality of energy harvesting connectors coupled to the straight energy harvesting components, such that the straight energy harvesting components and the energy harvesting connectors are arranged in a quadrilateral shape. Such an embodiment may receive vibration in three dimensions (e.g., X, Y, and Z dimensions) but converts the received vibration in two dimensions (e.g., X and Y dimensions). Additionally, such an embodiment may be flatter than the preceding embodiment, which can make it suitable for powering a thin or small electric device (e.g., a mobile device or a wearable device). For example, this embodiment can have dimensions of 8 cm×6 cm×0.5 cm and may include an energy storage component, such as a lithium-ion battery or supercapacitor circuit. More regarding this embodiment is discussed later herein with respect to FIGS. 9-13.

### Energy Harvesting Components

For some embodiments, an energy harvesting component may comprise an outer coil, a magnetic ring, an inner coil, a first stationary magnet, a second stationary magnet, and a rod. For some such embodiments, this energy harvesting component is implemented as a straight energy harvesting component. For the purposes of this detailed description, such an energy harvesting component may be regarded as a straight energy harvesting component. Alternatively, the energy harvesting component may be implemented as a non-linear energy harvesting component. The energy harvesting component may be contained within a tubular housing. The outer coil may be positioned about an axis and have a first inner circumference. The magnetic ring may be positioned about the axis, have a first outer circumference smaller than the first inner circumference, and have a second inner circumference. The inner coil may be positioned about the axis and have a second outer circumference smaller than the second inner circumference of the magnetic ring. The first stationary magnet may be disposed on a first surface (e.g., an inner surface) of the energy harvesting component and aligned in repulsion to the magnetic ring. In particular, the first stationary magnet may comprise a first plurality of magnets disposed on the first surface, in a ring formation about the axis, to which the rod is aligned. Alternatively, the first stationary magnet may comprise a single magnet (e.g., a ring-formed magnet) disposed between a first end of the rod and the first surface. The second stationary magnet may be disposed on a second surface (e.g., an inner surface) of the energy harvesting component and aligned in repulsion to the magnetic ring. In particular, the second stationary magnet may comprise a second plurality of magnets disposed on the second surface, in a ring formation about the axis. Alternatively, the second stationary magnet may comprise another single magnet (e.g., a ring-formed magnet) disposed between a second end of the rod and the second surface.

The rod may extend from the first surface of the energy harvesting component to the second surface of the energy harvesting component, and be aligned with the axis. Accordingly, the first stationary magnet may be disposed at one end of the rod such that the first stationary magnet repels the magnetic ring away from the first surface as the magnetic ring moves along the rod, toward the first surface, at one end of the rod. Likewise, the second stationary magnet may be disposed at the other end of the rod such that the second stationary magnet repels the magnetic ring away from the second surface as the magnetic ring moves along the rod, toward the second surface, at the other end of the rod. For some embodiments, the magnetic force fields from the first and second stationary magnets keep the poles of the magnetic ring axially aligned within the energy harvesting component.

Additionally, the rod may pass through (e.g., the respective inner diameters of) the outer coil, the magnetic ring, and the inner coil such that the magnetic ring is movable along the axis between the first surface of the energy harvesting component and the second surface of the energy harvesting component. The inner coil may be disposed within the rod or on an outer surface of the rod. According to some embodiments, this movement of the magnetic ring along the axis generates electric energy by inducing a first current in the inner coil and inducing a second current in the outer coil as the magnetic ring moves along the axis.

For instance, electromagnetic energy conversion by the energy harvesting component described above may involve the movement of the magnetic ring (e.g., comprising a magnetic composite) through the inner and outer electrical coils of the energy harvesting component. Movement of the magnetic ring can subject the coils to a changing magnetic force field, which then induces an electric current in the coils. Based on the nature of the magnetic force field and the space between the inner and outer coils that permits the magnetic ring to move (along the rod), the B-field that results from the magnetic ring's movement and that intersects (e.g., “cuts through”) the inner coil may be an order of magnitude higher than the B-field in the outer coil.

For some embodiments, the magnetic ring comprises a magnetic composite that includes a plurality of hollow cylindrical magnets coupled together to form a single, larger hollow cylindrical magnet. According to some embodiments, the rod of an energy harvesting component passes through the hollow portion of the larger hollow cylindrical magnet as the magnetic ring moves along the rod. Additionally, for some embodiments, the hollow cylindrical magnets are coupled such that adjacent hollow cylindrical magnets are coupled with their poles in repulsion. Coupling the hollow cylindrical magnets in this manner can cause the resulting magnetic composite to create regions of strong magnetic B-field, which can intersect (e.g., “cut through”) both an inner coil and an outer coil of an energy harvesting component described herein. The coupling of any two hollow cylindrical magnets may be achieved by glue. Further, a thing solid sheet (e.g., thin metal sheet) may be disposed between any two hollow cylindrical magnets coupled together. A given hollow cylindrical magnet may comprise an individual permanent magnet, such as one comprising neodymium-iron-boron (NdFeB). The plurality of hollow cylindrical magnets may comprise an odd number of hollow cylindrical magnets greater than 1 (e.g., 3, 5, 7).

An electric power output of an energy harvesting component may be dependent on a frequency and vibrational force or acceleration received by (e.g., applied to) the energy harvesting component. For instance, a straight energy harvesting component may produce a power density of up to 54 mWcm⁻³ g⁻² based on a 4 Hz vibration and a force acceleration of 1 g=9.8 m/s². The energy harvesting component may be designed to harness vibrations with a wide range of low frequencies, such as 0.5-100 Hz, and a wide range of applied vibration force accelerations, such as 0.1-1.5 g. In this way, an energy harvesting component can harness vibrations due to walking, jogging, car/train/airplane/bicycle/motorbike motion, home appliances (e.g., washing machines, dryers, and dishwashers), industrial equipment, bridges, and other vibrating structures and environments.

### Energy Harvesting Connectors

As described herein, an energy harvesting connector may receive vibrations in one, two, or three dimensions, may transfer received vibrations to one energy harvesting component, may transfer vibrations received from one energy harvesting component to another energy harvesting component, and may convert received vibrations into electric energy. An energy harvesting connector may comprise two ends, and two or more bends between the ends. For instance, an energy harvesting connector may comprise a 90-degree bend, or a 45-degree bend. The energy harvesting connector may be contained within a tubular housing.

One or both ends of the energy harvesting connector may be coupleable to individual energy harvesting components. Depending on the embodiment, an energy harvesting connector described herein may couple to a single energy harvesting component or may couple two energy harvesting components together. For instance, an energy harvesting connector may couple to one end of a single, straight energy harvesting component, while in another instance, an energy harvesting connector may couple one end of a straight energy harvesting component to the end of another straight energy harvesting component.

An energy harvesting connector of an embodiment may comprise one or more mechanical, electromagnetic, piezoelectric, electrostatic, and fluidic mechanisms to receive vibrations, to transfer vibrations, to convert vibrations into electric energy, or to perform some combination thereof. The following embodiments of energy harvesting connectors are merely described for illustrative purposes and in no way limit the possibility of other embodiments.

### Fluidic Energy Harvesting Connector

For some embodiments, an energy harvesting connector comprises a duct, a first membrane disposed over a first end of the energy harvesting connector, a second membrane disposed over a second end of the energy harvesting connector, a first magnet coupled to the first membrane, and a second magnet coupled to the second membrane. For the purposes of this detailed description, such an energy harvesting connector may be regarded as a fluidic energy harvesting connector, or harvester-to-harvester fluidic connector. The first magnet coupled to the first membrane may be embedded in, or disposed on an outer surface of, the first membrane. Similarly, the second magnet coupled to the second membrane may be embedded in, or disposed on an outer surface of, the second membrane. For some embodiments, the first membrane is elastic, thereby permitting motion of the first magnet to cause the first membrane to expand and contract. Additionally, the first membrane may comprise a first piezoelectric material whose expansion or contraction due to motion by the first magnet generates electric energy. Similarly, the second membrane may be elastic, thereby permitting motion of the second magnet to cause the second membrane to expand and contract. The second membrane may comprise a second piezoelectric material whose expansion or contraction due to motion by the second magnet generates electric energy. Electrodes may be disposed on one or both of the first membrane or the second membrane to respectively capture electrons emitted during membrane expansion or contraction and provide the captured electrons as electric energy.

The duct may extend from a first end of the energy harvesting connector to a second end of the energy harvesting connector. Additionally, the duct may contain an incompressible fluid. As used herein, an incompressible fluid can include any fluid having a constant density, such as H₂O (water). By the incompressible fluid in the duct, the first and second magnets may be fluidically coupled to each other such that a first motion by the first magnet causes a second motion by the second magnet. Likewise, the fluidic coupling between the first and second magnets may be such that a third motion by the second magnet causes a fourth motion by the first magnet. The duct may narrow from a first cross-sectional area of the first end of the energy harvesting connector to a second cross-sectional area of the second end of the energy harvesting connector. The difference between the first and second cross-sectional areas may cause the second motion by the second magnet to be larger than (e.g., amplified over) the first motion by the first magnet.

An inner surface of the duct may comprise a first electrostatic material that generates electric energy in response to relative motion between at least a portion of the incompressible fluid and the inner surface of the duct. Additionally, the incompressible fluid may comprise a second electrostatic material whose relative motion with respect to the first electrostatic material generates electric energy. This use of the second electrostatic material can cause generation of more electric energy than would be generated with the first electrostatic material alone.

According to various embodiments, the energy harvesting connector is coupleable to an energy harvesting component that includes a magnetic ring, and the first magnet is coupled to the first membrane such that the first magnet is aligned in repulsion to the magnetic ring of the energy harvesting component. For instance, assume that an energy harvesting system comprises a first straight energy harvesting component and an energy harvesting connector, where a first end of the energy harvesting connector, nearest the first magnet of the energy harvesting connector, is coupled to the first straight energy harvesting component. Within the first straight energy harvesting component, the movement of a first magnetic ring toward the first end of the energy harvesting connector can cause the first magnet of the energy harvesting connector to repel away from the first magnetic ring, thereby causing the first motion.

As the first magnetic ring moves away from the first end of the energy harvesting connector, the first magnet of the energy harvesting connector may return toward the first magnet's at-rest position. Where the first membrane is elastic, the first magnet may continue to move back and forth (e.g., vibrate) for a period of time after the first magnetic ring has moved away from the first end of the energy harvesting connector and the first magnet is outside the magnetic force field of the first magnetic ring.

According to some embodiments, the energy harvesting connector is coupleable to another (e.g., a second) energy harvesting component that includes another magnetic ring, and the second magnet is coupled to the second membrane such that the second magnet is aligned in repulsion to the other magnetic ring of the other energy harvesting component. For instance, assume that the energy harvesting system described above further comprises a second straight energy harvesting component, where a second end of the above energy harvesting connector, nearest the second magnet of the energy harvesting connector, is coupled to the second straight energy harvesting component. As described herein, the first motion of the first magnet can cause the second motion of the second magnet by way of the incompressible fluid contained in the duct. The second motion of the second magnet can cause a second magnetic ring within the second straight energy harvesting component to repel away from the second end of the energy harvesting connector, thereby causing the second magnetic ring to move within the second straight energy harvesting component.

As the second magnetic ring moves (e.g., is repelled) away from the second end of the energy harvesting connector, the second magnet of the energy harvesting connector may return toward the second magnet's at-rest position. Where the second membrane is elastic, the second magnet may continue to move back and forth (e.g., vibrate) for a period of time after the second magnetic ring has moved away from the second end of the energy harvesting connector and the second magnet is outside the magnetic force field of the second magnetic ring.

Accordingly, for the energy harvesting system described above: vibration received by the first straight energy harvesting component can cause movement of the first magnetic ring within the first straight energy harvesting component; the movement of the first magnetic ring of the first straight energy harvesting component can cause the first motion of the first magnet of an energy harvesting connector; the first motion of the first magnet of the energy harvesting connector can cause the second motion of the second magnet of the energy harvesting connector; and the second motion of the second magnet of the energy harvesting connector can cause movement of the second magnetic ring within the second straight energy harvesting component. In this way, vibration received by the first straight energy harvesting component can be transferred to the second straight energy harvesting component by way of the energy harvesting connector coupling the components together. Additionally, during operation, each of the first energy harvesting component, the second energy harvesting component, and the energy harvesting connector may convert one or more of the movement of the magnetic rings, expansion or contraction of membranes caused by motion of the magnets, and movement of the incompressible fluid within the duct into electric energy.

Where the first end of the energy harvesting connector (nearest the first magnet) is uncoupled to an energy harvesting component, movement of the first magnet may be caused by vibrations received by the energy harvesting connector. More regarding this is described herein with respect to FIG. 9.

### Non-Fluidic Energy Harvesting Connector

For some embodiments, an energy harvesting connector comprises a tube including a first magnet and a second magnet, and a rod extending from a first end of the energy harvesting connector to a second end of the energy harvesting connector. For the purposes of this detailed description, such an energy harvesting connector may be regarded as a non-fluidic energy harvesting connector, or a harvester-to-harvester non-fluidic connector.

The tube may comprise a plastic material. The first magnet may be disposed at a first end of the tube and the second magnet may be disposed at a second end of the tube. For instance, the first magnet may be disposed along a first outer edge of a first opening of the first end of the tube, and the second magnet may be disposed along a second outer edge of a second opening of the second end of the tube. Alternatively, the first magnet may be disposed along a first external surface at an opening of the first end of the tube, and the second magnet may be disposed along a second external surface at an opening of the second end of the tube. The first magnet may comprise a first magnetic ring, and the second magnet may comprise a second magnetic ring.

For some embodiments, the rod is longer than the tube is from the first end of the tube to the second end of the tube. The rod may have at least one bend (e.g., 90-degree bend). Additionally, the rod may pass through (e.g., the inner diameter of) the tube from the first end of the tube to the second end of the tube such that the tube is movable along the rod between the first end of the energy harvesting connector and the second end of the energy harvesting connector. For various embodiments, the rod passes through the first end of the tube by passing through an opening of the first magnet (e.g., where the first magnet is disposed along an outer edge of an opening of the first end of the tube). Likewise, for various embodiments, the rod passes through the second end of the tube by passing through an opening of the second magnet.

According to various embodiments, movement of the tube in a first direction along the rod causes the first magnet to move away from the first end of the energy harvesting connector and the second magnet to move toward the second end of the energy harvesting connector. Additionally, for some such embodiments, movement of the tube in a second direction along the rod causes the first magnet to move toward the first end of the energy harvesting connector and the second magnet to move away from the second end of the energy harvesting connector.

For some embodiments, the energy harvesting connector is coupleable to an energy harvesting component that includes a magnetic ring, and the first magnet of the energy harvesting connector is oriented such that the first magnet is aligned in repulsion to the magnetic ring of the energy harvesting component. Additionally, for some embodiments, the energy harvesting connector is coupleable to another (e.g., a second) energy harvesting component that includes another magnetic ring, and the second magnet of the energy harvesting connector is oriented such that the second magnet is aligned in repulsion to the magnetic ring of the energy harvesting component.

The description that follows includes systems, methods, techniques, instruction sequences, and computing machine program products that embody illustrative embodiments of the disclosure. In the following description, for the purposes of explanation, numerous specific details are set forth in order to provide an understanding of various embodiments of the inventive subject matter. It will be evident, however, to those skilled in the art, that embodiments of the inventive subject matter may be practiced without these specific details. In general, well-known instruction instances, protocols, structures, and techniques are not necessarily shown in detail.

Reference will now be made in detail to embodiments of the present disclosure, examples of which are illustrated in the appended drawings. The present disclosure may, however, be embodied in many different forms and should not be construed as being limited to the embodiments set forth herein.

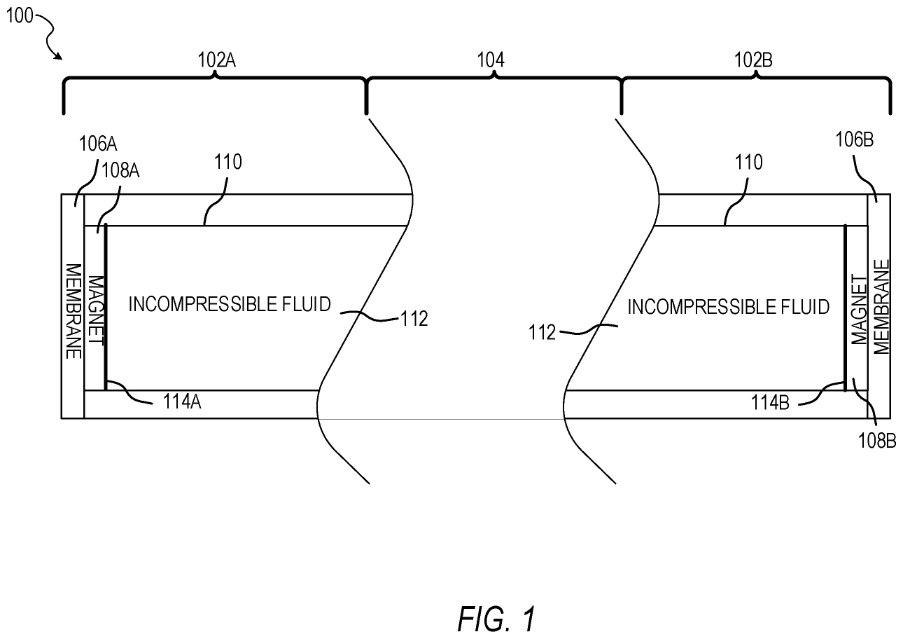

FIG. 1 is a diagram illustrating an example energy harvesting connector 100, according to some embodiments. In particular, FIG. 1 presents a lengthwise cross-sectional view of the energy harvesting connector 100. As shown, the energy harvesting connector 100 comprises end portions 102a, 102b and a middle portion 104. The middle portion 104 may comprise one or more bends, such as a single 90-degree bend. At least one of the end portions 102a, 102b may be coupled to an individual energy harvesting component. The energy harvesting connector 100 comprises a duct 110 extending from the end portion 102a to the other end portion 102b. The duct 110 includes an incompressible fluid 112. The duct 110 may comprise a fluid duct capable of containing the incompressible fluid 112 when end openings of the duct 110 are covered. Additionally, the duct 110 may comprise a tubular duct.

As shown, each end opening of the duct 110 is covered by a movable plate 114a, 114b. Each end of the end portions 102a, 102b is covered by a membrane 106a, 106b. A magnet 108a is disposed between, and coupled to, the membrane 106a and the movable plate 114a. A magnet 108b is disposed between, and coupled to, the membrane 106b and the movable plate 114b.

The movable plates 114a, 114b may prevent the incompressible fluid 112 coming into contact with the magnets 108a, 108b. The movable plates 114a, 114b may be used when an opening of the duct 110 is larger than the magnets 108a, 108b. One or more of the membranes 106a, 106b may comprise a piezoelectric material. Motion (e.g., vibration) of the magnet 108a can cause expansion or contraction of the membrane 106a, and expansion or contraction of the membrane 106a can generate electric energy where the membrane 106a comprises a piezoelectric material. Likewise, motion (e.g., vibration) of the magnet 108b can cause expansion or contraction of the membrane 106b, and expansion or contraction of the membrane 106b can generate electric energy where the membrane 106b comprises a piezoelectric material.

The inner surface of the duct 110 may comprise a first electrostatic material that generates electric energy in response to relative motion between at least a portion of the incompressible fluid 112 and the inner surface of the duct 110. As the incompressible fluid 112 rubs against the inner surface of the duct 110, this can generate electrostatic charge that can be captured as electric energy. To generate additional electric energy, the incompressible fluid 112 may comprise a second electrostatic material whose relative motion with respect to the first electrostatic material generates more electric energy than the first electrostatic material alone. Electrodes may be disposed on an inner surface of the duct 110 to capture electrostatic charge generated by motion of the incompressible fluid 112 relative to the inner surface of the duct 110, and to provide the captured electrostatic charge as electric energy.

Though not shown, for some embodiments, the duct 110 narrows from a first cross-sectional area of the end portion 102b to a second cross-sectional area of the end portion 102a. This narrowing of the duct 110 in this manner can amplify the motion (e.g., vibration) of the magnet 108a caused by the motion (e.g., vibration) of the magnet 108b via the incompressible fluid 112.

According to some embodiments, the magnet 108a is designed and positioned in the energy harvesting connector 100 such that the magnet 108a is outside (e.g., just outside) the magnetic force field of an at-rest magnetic ring of an energy harvesting component (not shown) coupled to the end portion 102a of the energy harvesting connector 100. The magnetic force field of the magnet 108a can enter within the magnetic force field, or interact with stronger regions, of the magnetic ring of the energy harvesting component when the magnetic ring is in motion, such as when the magnetic ring is moving toward a coupling point between the energy harvesting connector 100 and the energy harvesting component.

Similarly, for some embodiments, the magnet 108b is designed and positioned in the energy harvesting connector 100 such that the magnetic force field of the magnet 108b is outside (e.g., just outside) the magnetic force field of an at-rest magnetic ring of an energy harvesting component (not shown) coupled to the end portion 102b of the energy harvesting connector 100. It may also possible for the magnetic force fields of both magnets (108b and the at-rest magnetic ring) to interact when the magnetic ring is at rest. The magnetic force field of the magnet 108b can enter within the magnetic force field of the magnetic ring of the energy harvesting component when the magnetic ring is in motion, such as when the magnetic ring is moving toward a coupling point between the energy harvesting connector 100 and the energy harvesting component.

As described herein, once the end portion 102b is coupled to an energy harvesting component, a magnetic ring of the energy harvesting component can move toward the coupling point (e.g., due to vibration received by the energy harvesting component), thereby causing the magnet 108b to move against the movable plate 114b as the magnetic force field of the magnet 108b enters the magnetic force field of the magnetic ring. Movement of the magnet 108b against the movable plate 114b can cause the membrane 106b, coupled to the magnet 108b, to expand. As noted herein, the membrane 106b can comprise a piezoelectric material, and the membrane 106b can generate electric energy upon expansion or contraction.

Movement of the magnet 108b against the movable plate 114b can also cause the magnet 108b to push the movable plate 114b toward the center of the duct 110, thereby causing the incompressible fluid 112 within the duct 110 to move toward the movable plate 114a. As the incompressible fluid 112 moves toward the movable plate 114a, the movable plate 114a can move against the magnet 108a and, thus, cause the magnet 108a to move the membrane 106a. Movement of the magnet 108a against the membrane 106a can cause the membrane 106a, coupled to the magnet 108a, to expand. As noted herein, the membrane 106a can comprise a piezoelectric material, and the membrane 106a can generate electric energy upon expansion or contraction.

If the end portion 102a is coupled to another (second) energy harvesting component, movement of the magnet 108b against the movable plate 114b can further cause the movable plate 114a to move against the magnet 108a, and that can cause the magnetic force field of the magnet 108a to enter the magnetic force field of a magnetic ring of the second energy harvesting component. As the magnetic force field of the magnet 108a enters the magnetic force field of the magnetic ring of the second energy harvesting component, the magnet 108a can cause this magnetic ring to move away from the coupling point between the second energy harvesting component and the energy harvesting connector 100. Accordingly, through the energy harvesting connector 100, movement of the magnetic ring within the first energy harvesting component, coupled to the end portion 102b, can cause movement of the magnetic ring within the second energy harvesting component, coupled to the end portion 102a. In this way, vibration received at the first energy harvesting component can be transferred to the second energy harvesting component through the energy harvesting connector 100. This can continue in a cycle until vibration is no longer received by (e.g., applied to) the first energy harvesting component.

Additionally, the reverse may also be possible, whereby through the energy harvesting connector 100, the movement of a magnetic ring within a second energy harvesting component, coupled to the end portion 102a, can cause movement of a magnetic ring within a first energy harvesting component, coupled to the end portion 102b. In this way, vibration received at the second energy harvesting component can be transferred to the first energy harvesting component through the energy harvesting connector 100.

As noted herein, the movement of a magnetic ring within its respective energy harvesting component can cause the energy harvesting component to generate electric energy by the inner and outer coils of the energy harvesting component.

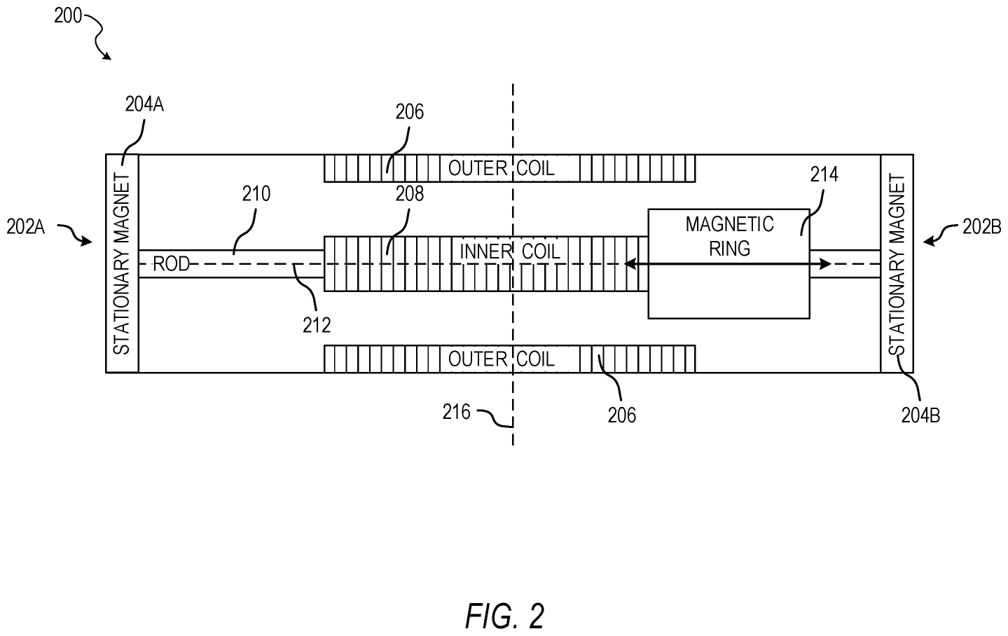

FIG. 2 is a diagram illustrating an example energy harvesting component 200, according to some embodiments. In particular, FIG. 2 presents a lengthwise cross-sectional view of the energy harvesting component 200. As shown, the energy harvesting component 200 comprises stationary magnets 204a, 204b, an outer coil 206, an inner coil 208, a rod 210, and a magnetic ring 214. As also shown, the energy harvesting component 200 is a straight energy harvesting component. The energy harvesting component 200 may be contained within a tubular housing. Each of the stationary magnets 204a, 204b is disposed on an inner surface of the energy harvesting component 200, at each end 202a, 202b of the energy harvesting component 200. According to some embodiments, the energy harvesting component 200 is coupleable to an energy harvesting connector (e.g., 100) by at least one of the end 202a or the end 202b.

The inner coil 208 is disposed within the rod 210 or on an outer surface of the rod 210, and positioned (e.g., wound) about an axis 212. The outer coil 206 is disposed (e.g., wound) about the axis 212. The outer coil 206 may further be disposed along the inner surface of the energy harvesting component 200, along the outer surface of the energy harvesting component 200 (e.g., outside the tubular housing wall), or within the housing wall of the energy harvesting component 200 (e.g., within the tubular housing wall). According to some embodiments, the inner coil 208 comprises a first conductive material (e.g., copper wire) and the outer coil 206 comprises a second conductive material (e.g., copper wire). The magnetic ring 214 is also positioned about the axis 212. The rod 210 extends between inner surfaces of the energy harvesting component 200 at each of the ends 202a, 202b, and passes through (e.g., the inner diameter of) the magnetic ring 214. By this arrangement, the rod 210 can keep the magnetic ring 214, and its magnetic poles, in alignment with the axis 212. As described herein, for some embodiments, the magnetic ring 214 comprises a magnet composite (e.g., where adjacent hollow cylindrical magnets of the magnet composite are coupled with their poles in repulsion).

The inner circumference of the outer coil 206 may be larger than the outer circumference of the magnetic ring 214, and the outer circumference of the inner coil 208 may be smaller than the inner circumference of the magnetic ring 214, thereby permitting the magnetic ring 214 to move along the axis 212 between the ends 202a, 202b of the energy harvesting component 200. According to some embodiments, the magnetic ring 214 is aligned such that the stationary magnet 204a repels the magnetic ring 214 as the magnetic ring 214 moves toward the end 202a and the magnetic force field of the of the magnetic ring 214 enters the magnetic force field of the stationary magnet 204a, and such that the stationary magnet 204b repels the magnetic ring 214 as the magnetic ring 214 moves toward the end 202b and the magnetic force field of the magnetic ring 214 enters the magnetic force field of the stationary magnet 204b. At least one of the stationary magnets 204a, 204b may comprise a ring-formed magnet disposed at or near the end of the rod 210 and about the axis 212. Alternatively, at least one of the stationary magnets 204a, 204b may comprise a plurality of magnets disposed at or near the end of the rod 210 and in a ring formation about the axis 212.

When the energy harvesting component 200 is not receiving vibration (e.g., in a non-vibrating environment), the magnetic ring 214 may be positioned at or near a center 216 of the energy harvesting component 200 with respect to the ends 202a, 202b, which may represent the magnetic ring 214's at-rest position. Additionally, each of the stationary magnets 204a, 204b may comprise a magnetic force field such that when the energy harvesting component 200 oriented horizontally (with respect to the Earth) and the magnetic ring 214 is positioned at or near the center 216 of the energy harvesting component 200, the magnetic ring 214 is outside the magnetic force field.

According to some embodiments, when the energy harvesting component 200 receives vibration in a given direction, the vector component of the vibration that aligns with the axis 212 causes the magnetic ring 214 to move along the rod 210. Additionally, according to some embodiments, as the magnetic ring 214 nears either of the ends 202a, 202b, the stationary magnets 204a, 204b repel the magnetic ring 214 away from the ends 202a, 202b. As described herein, as the magnetic ring 214 moves along the rod 210, and passes between the outer coil 206 and the inner coil 208, the magnetic force field from the magnetic ring 214 can induce a first electric current in the inner coil 208 and a second electric current in the outer coil 206.

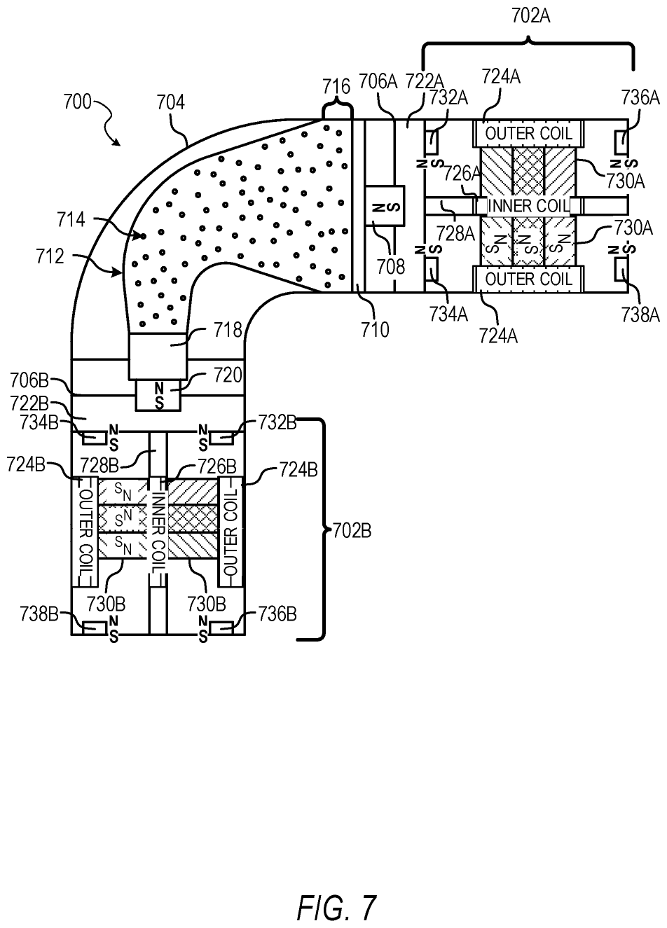

More regarding embodiments of energy harvesting components is discussed below with respect to FIGS. 7-9.

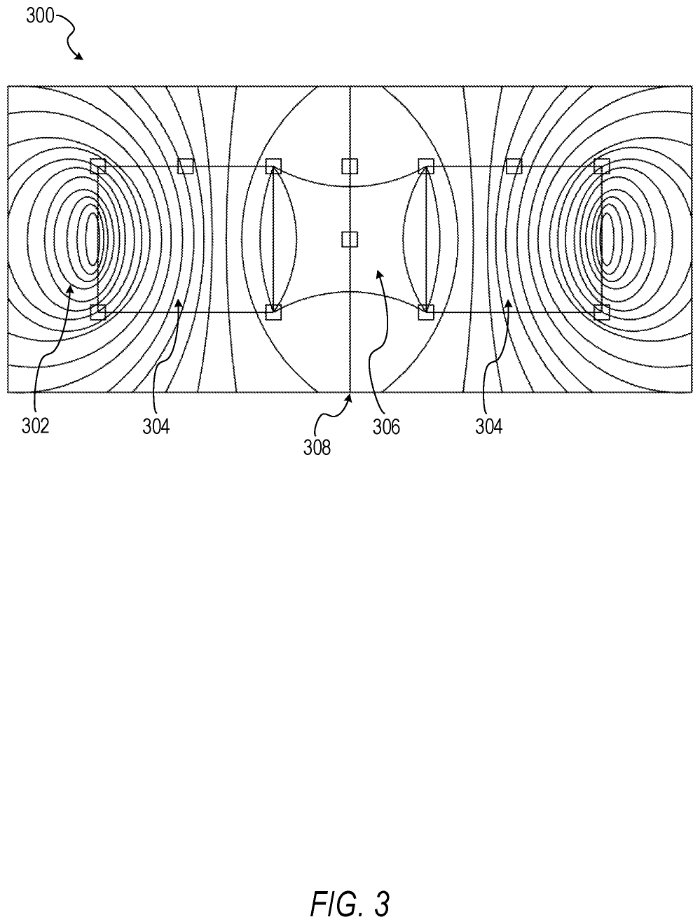

FIG. 3 is a heat map 300 illustrating an example average magnetic flux density from a magnetic ring 304 of an energy harvesting component, according to some embodiments. In particular, the magnetic ring 304 comprises a magnet composite including adjacent hollow cylindrical magnets coupled together with their poles in repulsion. According to some embodiments, reference 302 points to a location of an outer coil of an energy harvesting component, reference 306 points to a location of an inner coil of the energy harvesting component, and reference 308 points to a location of a rod of the energy harvesting component. As shown, the magnetic force field distribution shows two regions of strongly concentrated magnetic force field. For some embodiments, the respective locations of the inner coil and the outer coil are such that the inner coil and the outer coil can leverage the two strong regions of magnetic force field. These locations can provide optimum or near optimum electric energy generation by the inner coil and the outer coil as the magnetic ring 304 moves within the energy harvesting component, as described herein. As also shown, the electric energy generated by the inner coil may be significantly higher than the electric energy generated by the outer coil due to the higher magnetic force field emitted in the inner diameter of the magnetic ring 304.

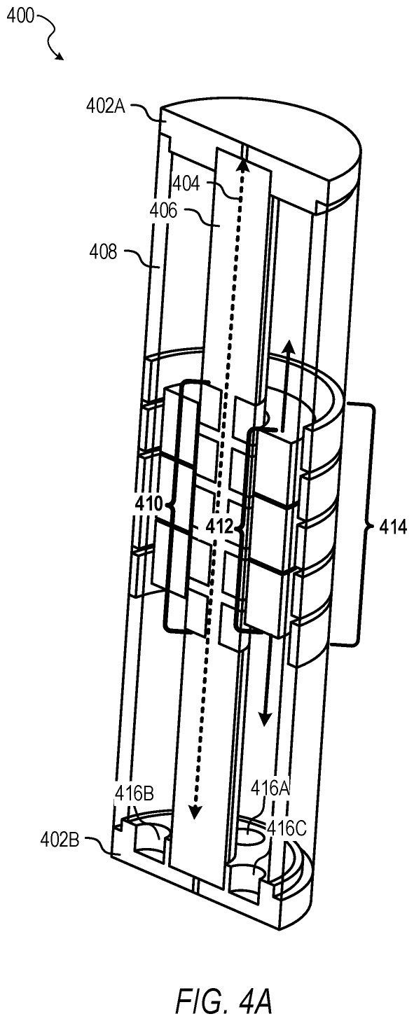

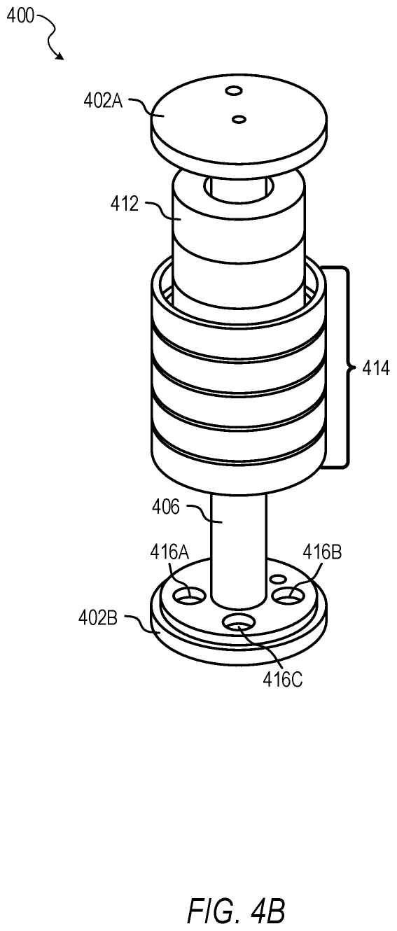

FIG. 4A is a diagram illustrating an example energy harvesting component 400, according to some embodiments. In particular, FIG. 4A presents a lengthwise cross-sectional view of the energy harvesting component 400. As shown, the energy harvesting component 400 comprises a straight energy harvesting component. The energy harvesting component 400 comprises ends 402a, 402b, a rod 406, an inner coil 410 disposed on the rod 406, a magnetic ring 412 disposed within a tubular wall 408, an outer coil 414, and stationary magnets 416a, 416b, 416c disposed on the end 402b. The rod 406 is aligned with respect to an axis 404. Though not shown, four stationary magnets 416 can be disposed (e.g., embedded), on the end 402b, in a ring formation about the rod 406. Likewise, though not shown, four stationary magnets similar to the stationary magnets 416 may be disposed, on the end 402a, in a ring formation about the rod 406. Each of the inner coil 410, the outer coil 414, and the magnetic ring 412 is disposed about the axis 404. According to some embodiments, the inner diameter of the outer coil 414 and the outer diameter of the inner coil 410 are such that the magnetic ring 412 can move along the rod 406. As described herein, as the magnetic ring 412 moves along the rod 406, the magnetic force field of the magnetic ring 412 can intersect with the inner coil 410 to induce electric current in the inner coil 410, and the magnetic force field of the magnetic ring 412 can intersect with the outer coil 414 to induce electric current in the outer coil 414. Additionally, as the magnetic ring 412 nears either of the ends 402a, 402b of the energy harvesting component 400, the magnetic force field of the magnetic ring 412 can enter the magnetic force field of the stationary magnets (e.g., the stationary magnets 416) and be repelled back toward a center of the energy harvesting component 400. FIG. 4B presents an inner view of the energy harvesting component 400 without the axis 404, the tubular wall 408 and the inner coil 410 being visible.

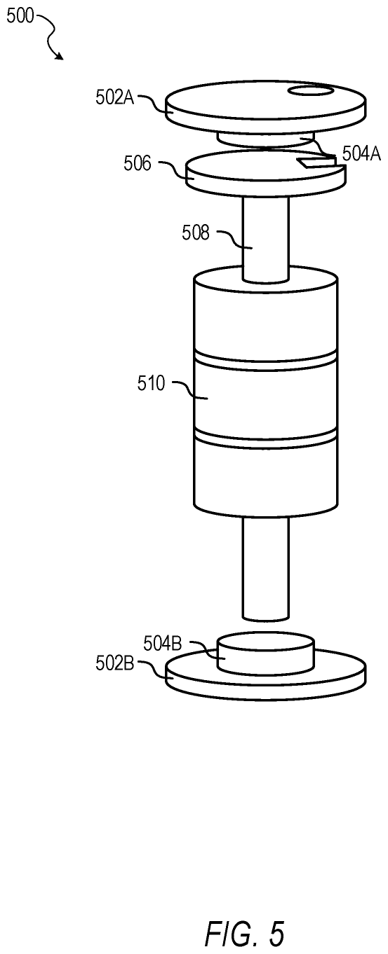

FIG. 5 is a diagram illustrating an example energy harvesting component 500, according to some embodiments. In particular, FIG. 5 presents an inner view of the energy harvesting component 500 without a tubular wall and an outer coil present. The energy harvesting component 500 comprises a straight energy harvesting component. The energy harvesting component 500 comprises ends 502a, 502b, a rod 508, a plastic extension component 506 of the rod 508 (used to provide a snug fit for the rod 508), an inner coil (not shown) disposed on the rod 508, a magnetic ring 510, and stationary magnets 504a, 504b respectively disposed at the ends 502a, 502b. As shown, each of the stationary magnets 504a, 504b comprises a single solid magnet disposed between the rod 508 and one of the ends 502a, 502b. For the energy harvesting component 500, the rod 508 can assist with axially aligning the magnetic ring 510 within the energy harvesting component 500.

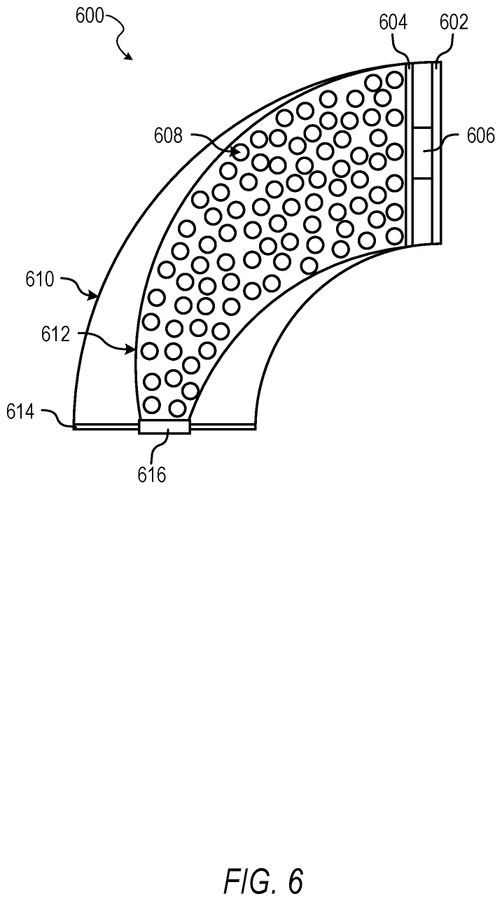

FIG. 6 is a diagram illustrating an example energy harvesting connector 600, according to some embodiments. In particular, FIG. 6 presents a lengthwise cross-sectional view of the energy harvesting connector 600. The energy harvesting connector 600 comprises a fluidic energy harvesting connector as described herein. As shown, the energy harvesting connector 600 comprises membranes 602, 614, magnets 606, 616, a movable plate 604, a duct 612, and an incompressible fluid 608 contained within the duct 612. One end of the duct 612 is coupled to the magnet 616, and the other end of the duct 612 is coupled to the movable plate 604. The cross section of the duct 612 narrows from the movable plate 604 to the magnet 616. The magnet 606 is disposed between the membrane 602 and the movable plate 604, and the magnet 606 is coupled to both the membrane 602 and the movable plate 604. The magnet 616 is coupled to (e.g., embedded in) the membrane 614.

Motion of the magnet 606 may be due to being repelled by a magnetic ring of an energy harvesting component (coupled at an end of the energy harvesting connector 600 nearest the magnet 606), due to movement of the incompressible fluid 608 within the duct 612 (e.g., caused by the magnet 616), or due to vibration received by the energy harvesting connector 600. According to some embodiments, motion of the magnet 606 causes expansion or contraction of the membrane 602 and causes movement of the incompressible fluid 608 within the duct 612 via the movable plate 604. As described herein, the membrane 602 may be flexible, and may comprise a first piezoelectric material that causes the membrane 602 to generate electric energy as the membrane 602 expands due to motion of the magnet 606.

Similarly, motion of the magnet 616 may be due to being repelled by a magnetic ring of an energy harvesting component (coupled at an end of the energy harvesting connector 600 nearest the magnet 616), due to movement of the incompressible fluid 608 within the duct 612 (e.g., caused by the movable plate 604), or due to vibration received by the energy harvesting connector 600. The energy harvesting connector 600 comprises a housing 610 that contains the magnet 606, the movable plate 604, the incompressible fluid 608, and the duct 612. According to some embodiments, motion of the magnet 616 causes expansion or contraction of the membrane 614 and causes movement of the incompressible fluid 608 within the duct 612. As described herein, the membrane 614 may be flexible, and may comprise a second piezoelectric material that causes the membrane 614 to generate electric energy as the membrane 614 expands due to motion of the magnet 616.

The inner surface of the duct 612 may comprise a first electrostatic material, which can cause generation of electric energy as the incompressible fluid 608 moves relative to the inner surface. The incompressible fluid 608 may further comprise a second electrostatic material, which can cause, or assist in, generation of electric energy as the incompressible fluid 608 moves relative to the inner surface. The second electrostatic material may cause additional generation of electric energy over the first electrostatic material alone.

For some embodiments, a first motion of the magnet 606 causes the movable plate 604 to move toward the incompressible fluid 608 within the duct 612. For some embodiments, the resulting movement of the incompressible fluid 608 by the movable plate 604 causes a second motion of the magnet 616.

For some embodiments, a third motion of the magnet 616 causes the incompressible fluid 608 to move within the duct 612. For some embodiments, the resulting movement of the incompressible fluid 608, by the third motion of the magnet 616, causes movement of the movable plate 604, thereby causing a fourth motion of the magnet 606.

FIG. 7 is a diagram illustrating an example energy harvesting system 700 comprising an energy harvesting connector 704 that couples together a straight energy harvesting component 702a and a straight energy harvesting component 702b, according to some embodiments. In particular, FIG. 7 presents a lengthwise cross-sectional view of the energy harvesting system 700. The energy harvesting connector 704 comprises a fluidic energy harvesting connector as described herein. As shown, the energy harvesting connector 704 comprises a coupling point 722a for coupling to the straight energy harvesting component 702a; a coupling point 722b for coupling to the straight energy harvesting component 702b; membranes 706a, 706b; magnets 708, 720; movable plates 710, 718; and a duct 712 containing an incompressible fluid 714. The magnet 708 is coupled to the membrane 706a and the movable plate 710. The magnet 720 is coupled to the membrane 706b and the movable plate 718. The duct 712 extends from the movable plate 710 to the movable plate 718, and the cross section of the duct 712 narrows from the movable plate 710 to the movable plate 718. A straight region 716 is disposed between the opening of the duct 712 and the movable plate 710, which provides the movable plate 710 with space within the energy harvesting connector 704 to move toward the duct 712 and push the incompressible fluid 714 into the duct 712.

The straight energy harvesting component 702a is coupled to the energy harvesting connector 704 at the coupling point 722a. The straight energy harvesting component 702a comprises a rod 728a extending the length of the straight energy harvesting component 702a, an outer coil 724a disposed within an inner surface of the straight energy harvesting component 702a, an inner coil 726a disposed about the rod 728a, and a magnetic ring 730a disposed about the rod 728a and movable along the rod 728a. The straight energy harvesting component 702a comprises stationary magnets 732a, 734a disposed on an inner surface at an end of the straight energy harvesting component 702a nearest the coupling point 722a, and stationary magnets 736a, 738a disposed on an inner surface at the other end of the straight energy harvesting component 702a. As shown, the magnetic ring 730a comprises a magnet composite including adjacent magnets coupled together with their poles aligned in repulsion. As also shown, the stationary magnets 732a, 734a, 736a, 738a are disposed such that their respective poles are aligned in repulsion to the outermost poles of the magnetic ring 730a. Additionally, the outermost pole of the magnetic ring 730a closest the coupling point 722a is aligned in repulsion to the magnet 708. As described herein, the magnet 708 may be designed and located outside the magnetic force field of the magnetic ring 730a when the magnetic ring 730a is at rest (e.g., positioned in the center of the straight energy harvesting component 702a).

The straight energy harvesting component 702b is similar to the straight energy harvesting component 702a, but coupled to the energy harvesting connector 704 at the coupling point 722b. As described herein, the magnet 720 may be designed and located outside the magnetic force field of the magnetic ring 730b when the magnetic ring 730b is at rest (e.g., positioned in the center of the straight energy harvesting component 702b).

According to some embodiments, movement of the magnet 708 is caused by the repulsion of the magnet 708 as the magnetic ring 730a moves toward the coupling point 722a and the magnetic force field of the magnet 708 enters the magnetic force field of the magnetic ring 730a. The movement of the magnet 708 may cause the movable plate 710 to push the incompressible fluid 714 into the duct 712. As the movable plate 710 pushes the incompressible fluid 714 into the duct 712, the incompressible fluid 714 can cause the movable plate 718 to move toward the magnet 720. Movement of the magnet 720 can cause the membrane 706b to expand. The magnet 720 can also move toward the magnetic ring 730b of the straight energy harvesting component 702b, thereby causing the magnetic ring 730b to repel away from the magnet 720 as the magnetic force field of the magnetic ring 730b enters the magnetic force field of the magnet 720.

For some embodiments, the repulsion between various magnets of the energy harvesting system 700 and the movement of the incompressible fluid 714 provide a spring-force system that can define the vibration of the magnetic rings 730a, 730b. As a result, this spring-force system may be nonlinear and wideband in response to applied vibration.

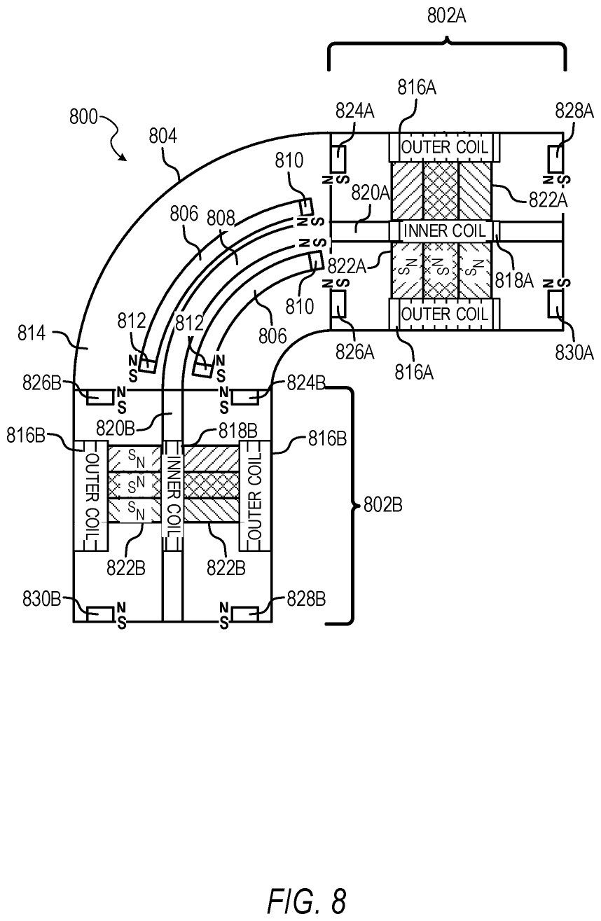

FIG. 8 is a diagram illustrating an example energy harvesting system 800 comprising an energy harvesting connector 804 that couples together a straight energy harvesting component 802a and a straight energy harvesting component 802b, according to some embodiments. In particular, FIG. 8 presents a lengthwise cross-sectional view of the energy harvesting system 800. The energy harvesting connector 804 comprises a non-fluidic energy harvesting connector as described herein. As shown, the energy harvesting connector 804 comprises an inner cavity 814 containing a rod 808 extending between the two ends of the energy harvesting connector 804, a tube 806, and magnets 810, 812. The rod 808 comprises at least one bend and extends between the two ends of the energy harvesting connector 804 that couple to the straight energy harvesting components 802a, 802b. Though the rod 808 shows a bend of 90 degrees, for some embodiments, the bend could be of a different angle. The rod 808 is longer than the tube 806 and passes through (e.g., the respective inner diameters of) a first end and a second end of the tube 806 such that the tube 806 is movable along the rod 808. Each of the magnets 810, 812 is disposed at an end of the tube 806, and may be disposed such that the rod 808 passes through (e.g., the respective inner diameters of) the magnets 810, 812 to pass through (e.g., the inner diameter of) the tube 806. At least one of the magnets 810, 812 may comprise a ring-formed magnet, and at least one of the magnets 810, 812 may be disposed along an outer edge of an opening of an end of the tube 806, or disposed along an external surface at an opening of an end of the tube 806.

The straight energy harvesting component 802a is coupled to the energy harvesting connector 804 at a first end of the energy harvesting connector 804. The straight energy harvesting component 802a comprises a rod 820a extending the length of the straight energy harvesting component 802a, an outer coil 816a disposed within an inner surface of the straight energy harvesting component 802a, an inner coil 818a disposed about the rod 820a, and a magnetic ring 822a disposed about the rod 820a and movable along the rod 820a. The straight energy harvesting component 802a comprises stationary magnets 824a, 826a disposed on an inner surface at an end of the straight energy harvesting component 802a nearest the energy harvesting connector 804, and stationary magnets 828a, 830a disposed on an inner surface at the other end of the straight energy harvesting component 802a. As shown, the magnetic ring 822a comprises a magnet composite including adjacent magnets coupled together with their poles aligned in repulsion. As also shown, the stationary magnets 824a, 826a, 828a, 830a are disposed such that their respective poles are aligned in repulsion to the outermost poles of the magnetic ring 822a. Additionally, the outermost pole of the magnetic ring 822a closest the energy harvesting connector 804 is aligned in repulsion to the magnet 810. As described herein, the magnet 810 may be designed and located outside the magnetic force field of the magnetic ring 822a when the magnetic ring 822a is at rest (e.g., positioned in the center of the straight energy harvesting component 802a).

The straight energy harvesting component 802b is similar to the straight energy harvesting component 802a, but coupled to the energy harvesting connector 804 at the other end of the energy harvesting connector 804. As described herein, the magnet 812 may be designed and located outside the magnetic force field of the magnetic ring 822b when the magnetic ring 822b is at rest (e.g., positioned in the center of the straight energy harvesting component 802b).

According to some embodiments, movement of the tube 806 along the rod 808 in a first direction away from the straight energy harvesting component 802a causes the magnet 810 to move away from the first end of the energy harvesting connector 804 and the magnet 812 to move toward the second end of the energy harvesting connector 804. The movement of the tube 806 along the rod 808 in the first direction may be caused by the repulsion of the magnet 810 as the magnetic ring 822a moves toward the energy harvesting connector 804 and the magnetic force field of the magnet 810 enters the magnetic force field of the magnetic ring 822a. As described herein, the magnetic ring 822a may move toward the energy harvesting connector 804 due to a vibration received by the straight energy harvesting component 802a. As the magnet 812 moves toward the second end of the energy harvesting connector 804, the magnet 812 can cause the magnetic ring 822b to move away from the energy harvesting connector 804 as the magnetic force field of the magnetic ring 822b enters the magnetic force field of the magnet 812 and is repelled by the magnet 812.

Additionally, according to some embodiments, movement of the tube 806 along the rod 808 in a second direction away from the straight energy harvesting component 802b causes the magnet 812 to move away from the second end of the energy harvesting connector 804 and the magnet 810 to move toward the first end of the energy harvesting connector 804. The movement of the tube 806 along the rod 808 in the second direction may be caused by the repulsion of the magnet 812 as the magnetic ring 822b moves toward the energy harvesting connector 804 and the magnetic force field of the magnet 812 enters the magnetic force field of the magnetic ring 822b. As described herein, the magnetic ring 822b may move toward the energy harvesting connector 804 due to a vibration received by the straight energy harvesting component 802b. As the magnet 810 moves toward the first end of the energy harvesting connector 804, the magnet 810 can cause the magnetic ring 822a to move away from the energy harvesting connector 804 as the magnetic force field of the magnetic ring 822a enters the magnetic force field of the magnet 810 and is repelled by the magnet 810.

For some embodiments, the repulsion between various magnets of the energy harvesting system 800 and the movement of the tube 806 provide a spring-force system that can define the vibration of the magnetic rings 822a, 822b.

FIG. 9 is a diagram illustrating an example energy harvesting system 900, according to some embodiments. As shown, the energy harvesting system 900 comprises four straight energy harvesting components 902a, 902b, 902c, 902d, and four energy harvesting connectors 904a, 904b, 904c, 904d. As also shown, the straight energy harvesting components 902a, 902b, 902c, 902d and the energy harvesting connectors 904a, 904b, 904c, 904d are arranged in a square shape. In particular, the straight energy harvesting component 902a is coupled to the energy harvesting connector 904a, the energy harvesting connector 904a is coupled to the straight energy harvesting component 902b, and the straight energy harvesting component 902b is coupled to the energy harvesting connector 904b. This forms two sides of the energy harvesting system 900. The straight energy harvesting component 902c is coupled to the energy harvesting connector 904c, the energy harvesting connector 904c is coupled to the straight energy harvesting component 902d, and the straight energy harvesting component 902d is coupled to the energy harvesting connector 904d. This forms the other two sides of the energy harvesting system 900. Depending on the embodiment, one or more of the energy harvesting connectors 904a, 904b, 904c, 904d may comprise a fluidic energy harvesting connector (e.g., 704) as described herein, or a non-fluidic energy harvesting connector (e.g., 804) as described herein.

According to some embodiments, the orientation of the straight energy harvesting components 902a, 902b, 902c, 902d and the energy harvesting connectors 904a, 904b, 904c, 904d permits the energy harvesting system 900 to receive vibration in three dimensions (e.g., X, Y, and Z dimensions) and convert the received vibration in two dimensions (e.g., X and Y dimensions). For instance, the orientation of the energy harvesting connector 904b can permit it to receive vibrations from the Z dimension, and vibrations received from the straight energy harvesting component 902b, which may receive vibrations in the X dimension. Likewise, the orientation of the energy harvesting connector 904d can permit it to receive vibrations from the Z dimension, and vibrations received from the straight energy harvesting component 902d, which may also receive vibrations in the X dimension. The straight energy harvesting component 902a may receive vibrations in the Y dimension, and may transfer those vibrations to the straight energy harvesting component 902b via the energy harvesting connector 904a. In the reverse, the straight energy harvesting component 902b may receive vibrations in the X dimension and transfer those vibrations to the straight energy harvesting component 902a via the energy harvesting connector 904a. Similarly, the straight energy harvesting component 902c may receive vibrations in the Y dimension, and may transfer those vibrations to the straight energy harvesting component 902d via the energy harvesting connector 904c. In the reverse, the straight energy harvesting component 902d may receive vibrations in the X dimension and transfer those vibrations to the straight energy harvesting component 902c via the energy harvesting connector 904c. In this way, the energy harvesting system 900 can ensure that the magnetic ring of each of the straight energy harvesting components 902a, 902b, 902c, 902d will vibrate when the energy harvesting system 900 receives vibrations in any of the three dimensions (e.g., X, Y, and Z). The energy harvesting system 900 may be suitable for inclusion within a thin mobile device, such as a smartphone or a tablet, or a wearable device, such as a smart watch, where the energy harvesting system 900 can power or charge a battery of the device.

In FIG. 9, the straight energy harvesting component 902a is shown with a tubular housing wall 906. The straight energy harvesting component 902d illustrates an outer coil 918 and ends 916a, 916b of the straight energy harvesting component 902d once its tubular housing wall is removed. The straight energy harvesting component 902c illustrates a magnetic ring 912, and stationary magnets 914a, 914b, 914c, 914d of the straight energy harvesting component 902c once its tubular housing wall and its outer coil are removed. The straight energy harvesting component 902b illustrates an inner coil 910 and a rod 908 of the straight energy harvesting component 902b once its tubular housing wall, its outer coil, and its magnetic ring are removed.

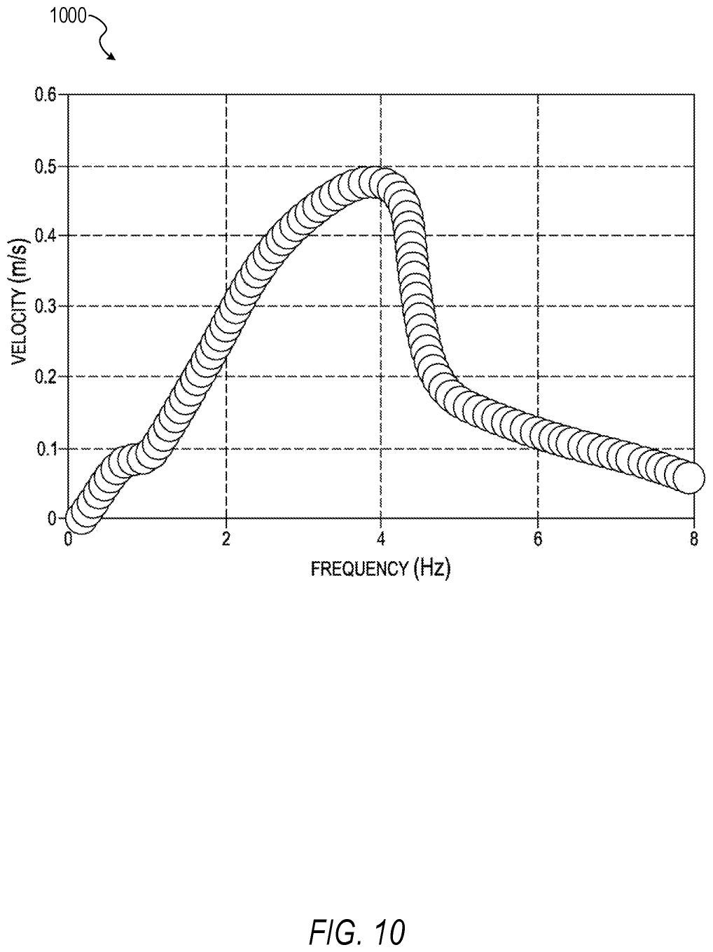

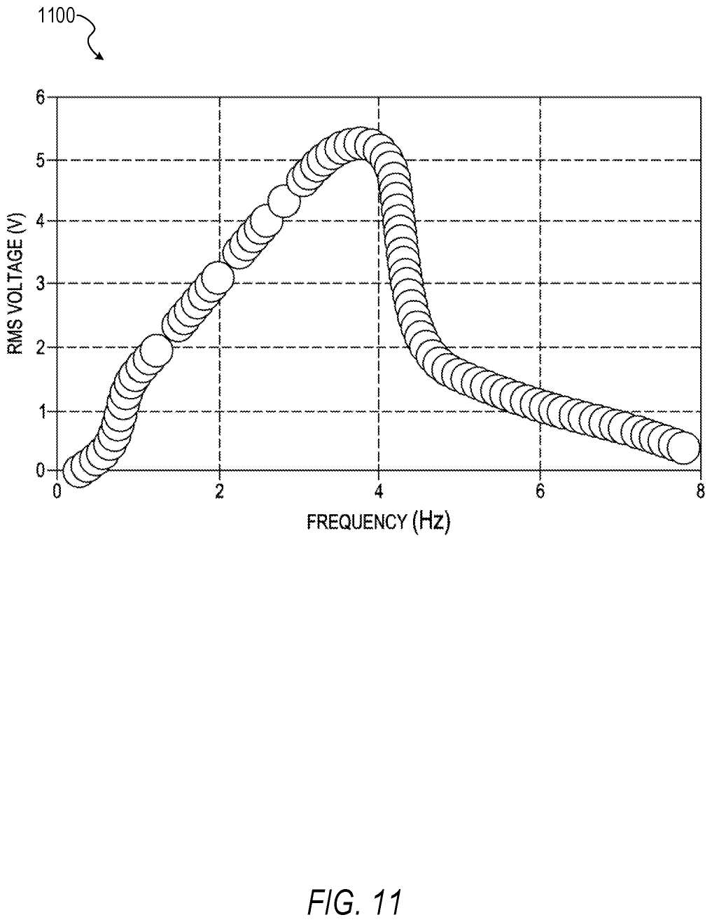

FIG. 10 is a chart 1000 illustrating an example velocity versus frequency of a magnetic ring of a straight energy harvesting component (e.g., 902a) in the energy harvesting system 900 of FIG. 9. FIG. 11 is a chart 1100 illustrating an example voltage output of a single, straight energy harvesting component, which may be part of the energy harvesting system 900 of FIG. 9 during operation. The velocity and voltage profiles illustrated by FIGS. 10 and 11 show a nonlinear and broadband profile enabled by the magnetic repulsion and interaction of the magnet composites via the energy harvesting connectors 904a, 904b, 904c, 904d when each of the energy harvesting connectors 904a, 904b, 904c, 904d comprises a fluidic energy harvesting connector (e.g., 704). By way of design choices applied to the energy harvesting system 900 (e.g., changes to magnets, coils, dimensions, etc.), the resonance frequencies of the energy harvesting system 900 can be tuned to ensure a uniform or near uniform voltage output across a wide range of frequencies (e.g., 0.5-100 Hz), which can fit a wide range of applications.

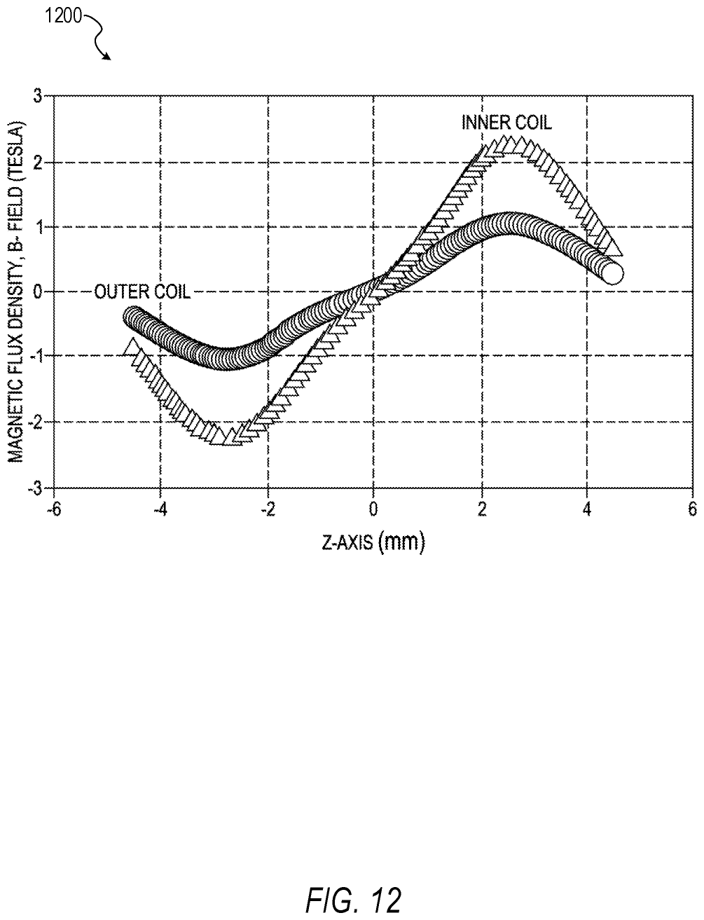

FIG. 12 is a chart 1200 illustrating an example average magnetic flux density intersecting an inner coil and an outer coil of a straight energy harvesting component (e.g., 902a), according to some embodiments.

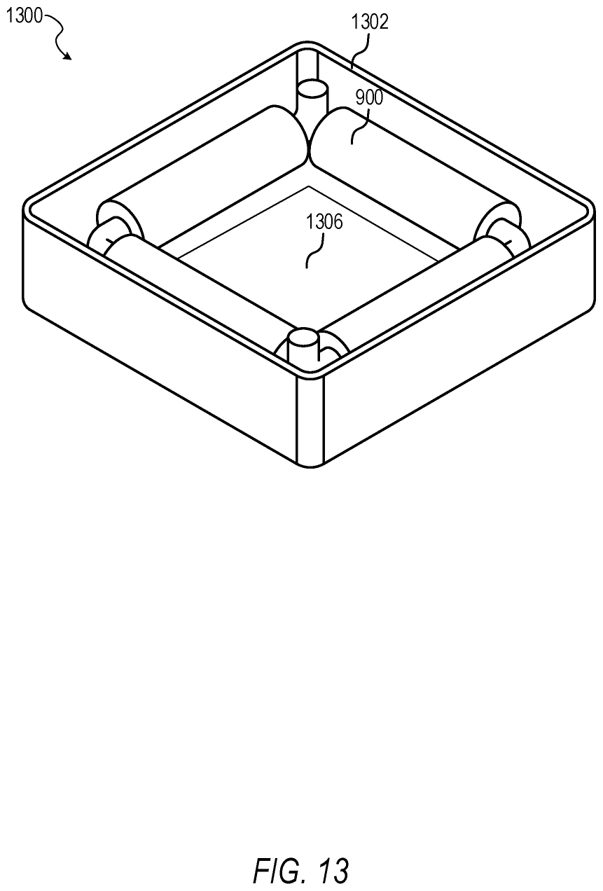

FIG. 13 is a diagram illustrating an example energy harvesting system 1300, according to some embodiments. As shown, the energy harvesting system 1300 comprises a housing 1302, the energy harvesting system 900 of FIG. 9 within the housing 1302, and an energy storage device 1306. Depending on the embodiment, the energy storage device 1306 may comprise a battery, such as a lithium-ion battery, or a supercapacitor. According to some embodiments, the electric energy produced by the energy harvesting system 900 (e.g., vibrations that the energy harvesting system 900 converts to electric energy) charges the energy storage device 1306. The form factor of the energy harvesting system 1300 may permit it to be included by a mobile device, such as a smartphone or tablet, or a wearable device, such as a smartwatch.

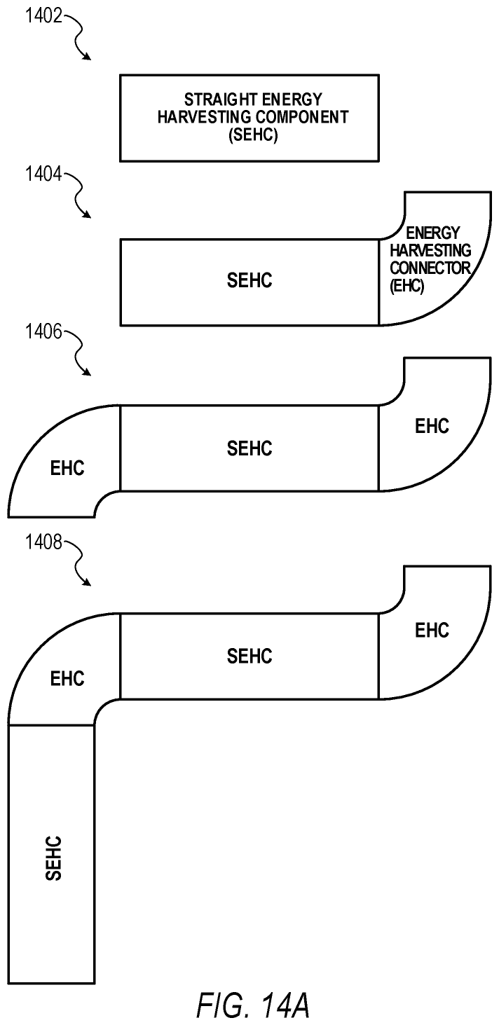

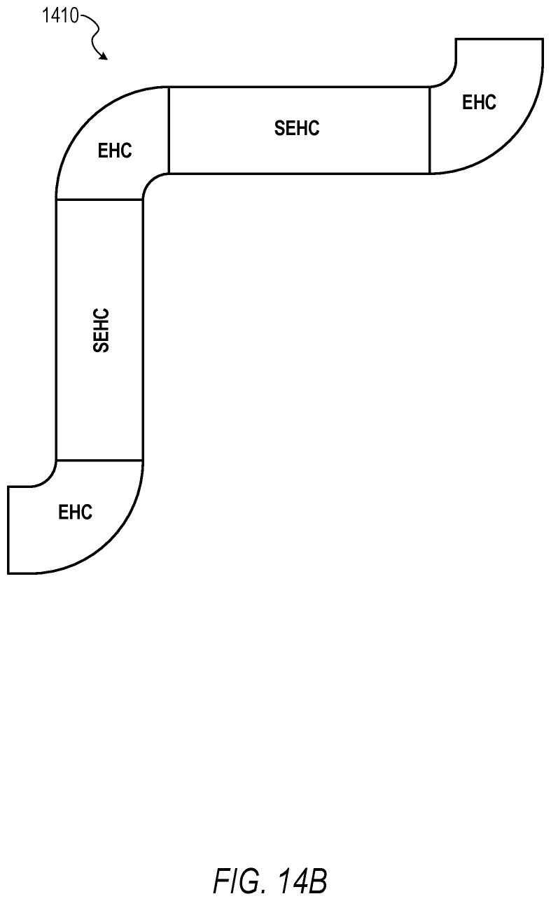

FIGS. 14A-14B provide multiple diagrams illustrating example configurations 1402-1410 of energy harvesting systems, according to some embodiments. As shown in FIG. 14A, configuration 1402 comprises a single straight energy harvesting component (SEHC). The SEHCs of configurations 1402-1410 may be similar to the energy harvesting component 200 of FIG. 2, the energy harvesting component 400 of FIGS. 4A and 4B, or the energy harvesting component 500 of FIG. 5.

Configuration 1404 comprises a single SEHC and a single energy harvesting connector (EHC) coupled to one end of the SEHC. The EHCs of configurations 1404-1410 may be similar to the energy harvesting connector 100 of FIG. 1, the energy harvesting connector 600 of FIG. 6, the energy harvesting connector 704 of FIG. 7, or the energy harvesting connector 804 of FIG. 8. Configuration 1406 comprises a single SEHC and two EHCs coupled to each end of the SEHC. As shown, in configuration 1406, one EHC is relatively oriented upward and the other EHC is relatively oriented downward. Configuration 1408 comprises two SEHCs coupled together by an EHC, and another EHC coupled to the other end of one of the SEHCs. In configuration 1408, the two SEHCs are oriented perpendicular to each other and, as such, can receive vibrations along perpendicular dimensions.

As shown in FIG. 14B, configuration 1410 comprises two SEHCs coupled together by an EHC, and two other EHCs coupled to the other ends of the SEHCs. As in configuration 1408, the two SEHCs of configuration 1410 are oriented perpendicular to each other and, as such, can receive vibrations along perpendicular dimensions.

“MOBILE DEVICE” in this context refers to any machine that includes a component requiring electricity for operation. Example mobile device may include, without limitation, a mobile phone, a portable digital assistant (PDA), a smartphone, a tablet, an ultra-book, a netbook, a laptop, or other mobile consumer electronics, such as a handheld game console, a wireless game console controller, or a radio. A mobile device may include a battery, which may be rechargeable by various embodiments described herein.

“WEARABLE DEVICE” in this context refers to any device that an individual can wear, such as apparel or an accessory. Example wearable device may include, without limitation, smartwatch, clip on device, jewelry, and part of apparel worn by an individual (e.g., shirt, pants, shorts, fitness wear, etc.). A wearable device may include a battery, which may be rechargeable by various embodiments described herein.

Throughout this specification, plural instances may implement components, operations, or structures described as a single instance. Structures and functionality presented as separate components in example configurations may be implemented as a combined structure or component. Similarly, structures and functionality presented as a single component may be implemented as separate components.

As used herein, the term “or” may be construed in either an inclusive or exclusive sense. The terms “a” or “an” should be read as meaning “at least one,” “one or more,” or the like. The presence of broadening words and phrases such as “one or more,” “at least,” “but not limited to,” or other like phrases in some instances shall not be read to mean that the narrower case is intended or required in instances where such broadening phrases may be absent. Additionally, boundaries between various components may be somewhat arbitrary, and particular operations are illustrated in a context of specific illustrative configurations. Other allocations of functionality are envisioned and may fall within a scope of various embodiments of the present disclosure. The specification and drawings are, accordingly, to be regarded in an illustrative rather than a restrictive sense.

It will be understood that changes and modifications may be made to the disclosed embodiments without departing from the scope of the present disclosure. These and other changes or modifications are intended to be included within the scope of the present disclosure.

1. An energy harvesting connector, comprising:
a duct containing an incompressible fluid and extending from a first end of the energy harvesting connector to a second end of the energy harvesting connector;
a first membrane disposed over the first end and a second membrane disposed over the second end;
a first magnet coupled to the first membrane; and
a second magnet coupled to the second membrane, the first and second magnets being fluidically coupled to each other by the incompressible fluid such that a first motion by the first magnet causes a second motion by the second magnet.

2. The energy harvesting connector of claim 1, wherein the first membrane comprises a first piezoelectric material whose expansion or contraction due to motion by the first magnet generates electric energy.

3. The energy harvesting connector of claim 2, wherein the second membrane comprises a second piezoelectric material whose expansion or contraction due to motion by the second magnet generates further electric energy.

4. The energy harvesting connector of claim 1, wherein an inner surface of the duct comprises a first electrostatic material that generates electric energy in response to relative motion between at least a portion of the incompressible fluid and the inner surface of the duct.

5. The energy harvesting connector of claim 4, wherein the incompressible fluid comprises a second electrostatic material whose relative motion with respect to the first electrostatic material generates electric energy.

6. The energy harvesting connector of claim 1, wherein the duct narrows from a first cross-sectional area closer to the first end of the energy harvesting connector to a second cross-sectional area closer to the second end of the energy harvesting connector, a difference between the first and second cross-sectional areas causing the second motion by the second magnet to be larger than the first motion by the first magnet.

7. The energy harvesting connector of claim 1, wherein the energy harvesting connector is coupleable to an energy harvesting component that includes a magnetic ring, the first magnet being coupled to the first membrane such that the first magnet is aligned in repulsion to the magnetic ring of the energy harvesting component.

8. (canceled)

9. (canceled)

10. (canceled)

11. (canceled)

12. (canceled)

13. An energy harvesting system comprising:
an energy harvesting component including a magnetic ring and having a first end; and
an energy harvesting connector coupled to the energy harvesting component at a first end of the energy harvesting connector, the energy harvesting connector including:
a duct containing an incompressible fluid and extending from the first end of the energy harvesting connector to a second end of the energy harvesting connector;
a first membrane disposed over the first end of the energy harvesting connector and a second membrane disposed over the second end of the energy harvesting connector;
a first magnet coupled to the first membrane such that movement of the magnetic ring toward the first magnet causes movement of the first magnet away from the magnetic ring by a magnetic force between the magnetic ring and the first magnet; and
a second magnet coupled to the second membrane, the first and second magnets being fluidically coupled to each other by the incompressible fluid such that a first motion by the first magnet causes a second motion by the second magnet.

14. The energy harvesting system of claim 13, wherein the first magnet is coupled to the first membrane such that the first magnet is aligned in repulsion to the magnetic ring.

15. The energy harvesting system of claim 13, wherein the energy harvesting component includes a rod positioned within the energy harvesting component such that the rod is aligned to an axis that is normal to the first membrane, and the magnetic ring is aligned to the axis such that a planar side of the magnetic ring faces the first membrane,

16. The energy harvesting system of claim 13, wherein the magnetic ring is positioned about an axis, and the energy harvesting component includes:
an outer coil positioned about the axis and having a first inner circumference, a first outer circumference of the magnetic ring being smaller than the first inner circumference of the outer coil;
an inner coil positioned about the axis and having a second outer circumference smaller than a second inner circumference of the magnetic ring;
a rod extending from a first surface to a second surface of the energy harvesting component, the rod aligned with the axis and passing through the outer coil, the magnetic ring, and the inner coil such that the magnetic ring moves along the axis between the first surface and the second surface; and
a stationary magnet disposed at each of the first and second surfaces and aligned in repulsion to the magnetic ring.

17. (canceled)

18. The energy harvesting system of claim 13, wherein at least one of the first membrane comprises a first piezoelectric membrane that, in response to expansion or contraction caused by motion of the first magnet, generates electric energy, or the second membrane comprises a second piezoelectric membrane that, in response to expansion or contraction caused by motion of the second magnet, generates electric energy.

19. The energy harvesting system of claim 13, wherein an inner surface of the duct comprises a first electrostatic material that, in response to relative motion between at least a portion of the incompressible fluid and the inner surface of the duct, generates electric energy.

20. (canceled)

21. The energy harvesting system of claim 13, wherein the duct narrows from a first cross-sectional area of the first end of the energy harvesting connector to a second cross-sectional area of the second end of the energy harvesting connector, a difference between the first and second cross-sectional areas causing the second motion by the second magnet to be larger than the first motion by the first magnet.

22. The energy harvesting system of claim 13, wherein the first magnet is coupled to the first membrane such that the first magnet is aligned in repulsion to the magnetic ring of the energy harvesting component.

23. (canceled)

24. The energy harvesting system of claim 13, comprising a second energy harvesting component coupled to the energy harvesting connector, the second energy harvesting component including a second magnetic ring, and the second magnet coupled to the second membrane such that movement of the second magnetic ring toward the second magnet causes movement of the second magnet away from the second magnetic ring by a second magnetic force between the second magnetic ring and the second magnet.

25. The energy harvesting system of claim 13, wherein the energy harvesting connector comprises a 90-degree connector.

26. The energy harvesting system of claim 13, comprising a second energy harvesting connector coupled to a second end of the energy harvesting component that is opposite the first end of the energy harvesting component.

27. (canceled)

28. The energy harvesting system of claim 13, comprising an energy storage unit to store electric energy generated by at least one of the energy harvesting component or the energy harvesting connector.

29. (canceled)

30. An energy harvesting connector, comprising:
a tube including a first magnet and a second magnet, the first magnet being disposed at a first end of the tube and the second magnet being disposed at a second end of the tube; and
a rod extending from a first end of the energy harvesting connector to a second end of the energy harvesting connector, the rod being longer than the tube is from the first end of the tube to the second end of the tube, the rod having at least one bend, and the rod passing through the tube from the first end of the tube to the second end of the tube such that the tube is movable along the rod between the first end of the energy harvesting connector and the second end of the energy harvesting connector.

31. (canceled)

32. (canceled)

33. (canceled)

34. (canceled)

35. (canceled)

36. (canceled)

37. (canceled)
